(19) United States
(12) Patent Application Publication
(10) Pub. No.: US 2004/0198044 A1
(43) Pub. Date: Oct. 7, 2004

(54) Stacking photoresist image transferring method for fabricating a packaging substrate

(76) Inventor: Sheng-Chuan Huang, Taoyuan Hsien (TW)

Correspondence Address: Rabin & Berdo, P.C., Suite 500, 1101 14th Street, Washington, DC, 20005, US

(21) Appl. No.: 10/406,388

(22) Filed: Apr. 4, 2003

(51) Int. Cl. H01L 21/44

(52) U.S. Cl. 438/684

(57) ABSTRACT

A stacking photoresist image transferring method for fabricating a packaging substrate has two photoresist image transferring processes to define copper wires and I/O pad areas and Ni—Au electrolytic plating areas. The second photoresist image transferring process limits the Ni—Au electrolytic plating areas to be only on the I/O pads to decrease fabricating coat. In addition, solder resist can be directly formed on the copper wires to increase a connecting strength of the solder resist on the substrate. Thus, the method according to the present invention can fabricate high reliable packaging substrates.

### BACKGROUND OF THE INVENTION

1. Field of the Invention

The present invention relates to a stacking photoresist image transferring method for fabricating a packaging substrate, and more specifically to a transferring method that can fabricate low cost and high quality packaging substrates.

2. Description of Related Art

Lately, packages for electronic devices, such as PBGA, Cavity Down BGA, MCM, CSP, Flip-Chip BGA, must be small to reduce size of a PCB. Each electronic device package has an exposed packaging substrate having lots of wires and I/P pads so a high density of wires must be laid out on the small packaging substrate. Therefore, the density of wires must be increased first so the size of the electronic device package can be reduced.

Further, the I/O pads on the packaging substrate such as bounding pads, ball pads, bumping pads are connected to other devices during packaging processes so each I/O pad requires a surface finishing process such as a Ni—Au coating to prevent surface oxidation and increase the adhesion strength.

With reference to FIG. 3, a packaging substrate (20) has two faces (201), four edges (202), wires (23) formed on the faces (201), I/O pads (22, 24) connected to the wires (23) and plating buses (21). The wires (23) and the I/O pads (22, 24) are made of copper. A plating bus (21) extends from each I/O pad (22, 24) to one edge (202) of the packaging substrate (20). The surface finishing process includes steps of coating a solder resist (not numbered) on the faces (201) of the packaging substrate (20) except for the I/O pads (22, 24) and plating a Ni—Au coating (not numbered) on each I/O pad (20). Thus, each I/O pad (22, 24) has a good connecting strength with contacts on a PCB (not shown). However, the packaging substrate (20) needs the plating bus (21) to deposit the Ni—Au coating on the I/O pads (22, 24). The plating bus (21) causes the following drawbacks with the packaging substrate.

(1) The plating bus (21) occupies wire layout area on the packaging substrate (20). Therefore the size of the packaging substrate (20) cannot be further reduced.

(2) Each plating bus (21) is a source electromagnetic interference that adversely affects the quality of transmitted signals.

Based on the forgoing description, the packaging substrate (20) with the surface finishing process has lots of drawbacks. A Full Body Gold (FBG) process for fabricating packaging substrate has been proposed. In the FBG process, an Au coating is first plated on wires and I/O pads on the faces of the packaging substrate (20), and then the Au coating further defines a pattern corresponding to the wires and I/O pads by an etching technique. Finally, a solder resist is coated on the entire faces except the I/O pads. Therefore, the packaging substrate has I/O pads coated the Au coating without the plating bus.

As above mentioned, the FBG process does not use plating buses so the packaging substrate can have a high density wires layout to reduce the size of the packaging substrate and does not have an electromagnetic interference problem. However, the FBG process uses 4 to 5 times more Au than the earlier surface finishing process. Therefore, the FBG process has high fabricating cost. In addition, the adhesion strength between the Au coating and the solder resist is weaker than the adhesion strength between the copper and solder resist, so the solder resist has a poor reliability after the package process.

The present invention provides an effective method for fabricating a packaging substrate to mitigate or obviate the aforementioned problems of each conventional method.

### SUMMARY OF THE INVENTION

An objective of the present invention is to provide a method of producing a packaging substrate without using plating buses and having a low fabricating cost and a good fabricating quality such as a good electronic features and a high connecting strength between solder resist and the packaging substrate.

Other objectives, advantages and novel features of the invention will become more apparent from the following detailed description when taken in conjunction with the accompanying drawings.

### BRIEF DESCRIPTION OF THE DRAWINGS

FIGS. 1A to 1H are side plan views of a substrate depicting the sequential states during the process of forming a first gap in the substrate in accordance with the present invention;

FIG. 2 is a top plan view of a packaging substrate in accordance with the present invention; and

FIG. 3 is a top plan view of a conventional package substrate with plating buses in accordance with the prior art.

### DETAILED DESCRIPTION OF THE PREFERRED EMBODIMENT

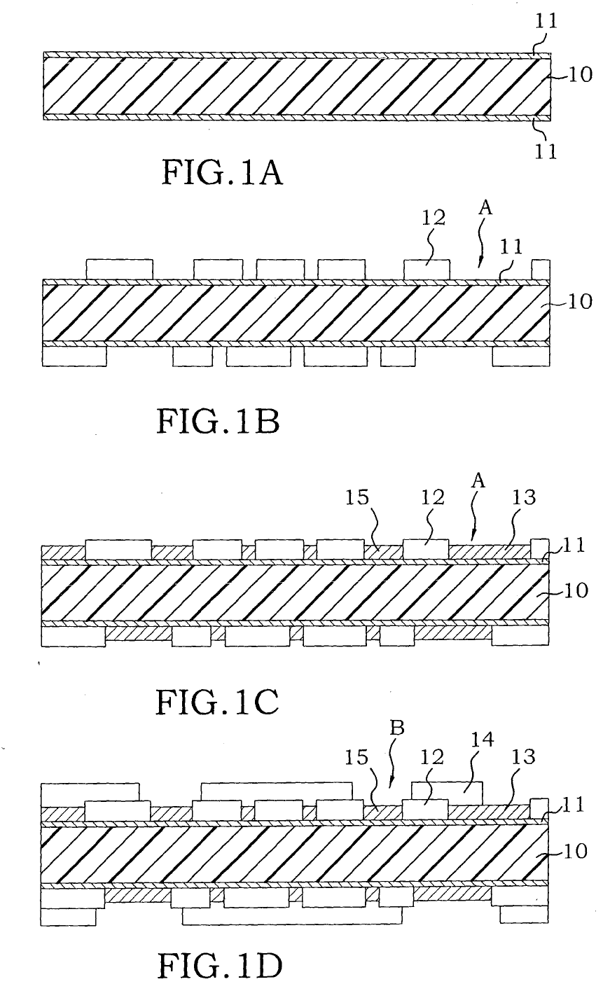

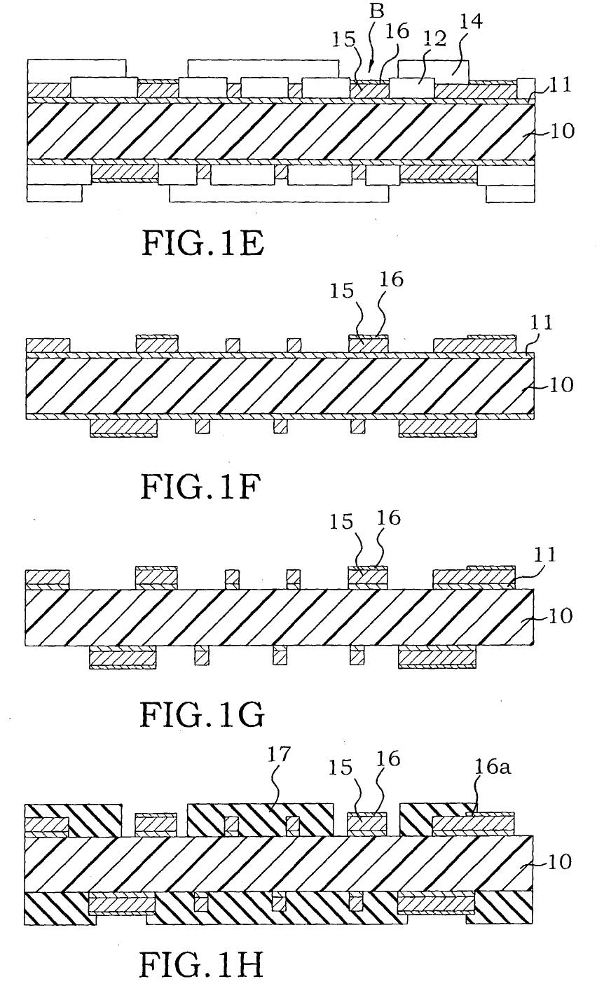

With reference to FIGS. 1A to 1H, a method for fabricating a packaging substrate in accordance with the present invention includes following steps of:

(a) preparing a substrate (10) having two opposite faces (not numbered);

(b) forming two thin base copper coatings (11) respectively on two faces, as shown in FIG. 1A;

(c) defining a first pattern of plating areas (A) on each thin base copper coating (11) with a first photoresist (12) in a photoresist image transferring process, as shown in FIG. 1B;

(d) plating a copper layer (13) in the plated copper areas (A) to be copper wires (not numbered) and I/O pads (15), as shown in FIG. 1C;

(e) defining a second pattern of plated Ni—Au electrolytic plating areas (B) on the I/O pads (15) by a second photoresist (14) using a photoresist image transferring process, as shown in FIG. 1D;

(f) plating a Ni—Au electrolytic plating (16) in the plated Ni—Au electrolytic plating areas (B) on the I/O pads (15), as shown in FIG. 1E;

(g) removing the first and second photoresist (12,14) to expose portions of each thin base copper coating (11) covered by the first photoresist (12), as shown in FIG. 1F;

(h) flash etching the exposed portion of the thin base copper coatings (11), as shown in FIG. 1G; and

(i) printing a solder resist pattern (17) on the copper wires, as shown in FIG. 1H. In addition, the solder resister pattern (17) can be further covered on edges of the Ni—Au electrolytic plating (16a).

The first and second photoresist (12,14) are made of a specific material such as a dry film, liquid film, solder mask, removable UV curing resin, etc. The first and second photoresit (12,14) can be removed by one stripping technique. The thin base copper coating (11) formed on the substrate (10) can be further processed by a chemical mechanical polishing (CMP) technique or etching technique to have a thinner cooper coating (11). An optimum thickness is about 1 to 5 um to easily execute step (h).

Based on the forgoing description, the method in accordance with the present invention has two photoresist image transferring steps without plating buses. The first image transferring step defines the plated copper wires and I/O pads, and the second image transferring step defines the plated Ni—Au electrolytic plating on the I/O pads. In addition, the solder resist is directly printed on the copper wires so the solder resist securely covers the packaging substrate.

Advantages of the present invention follow.

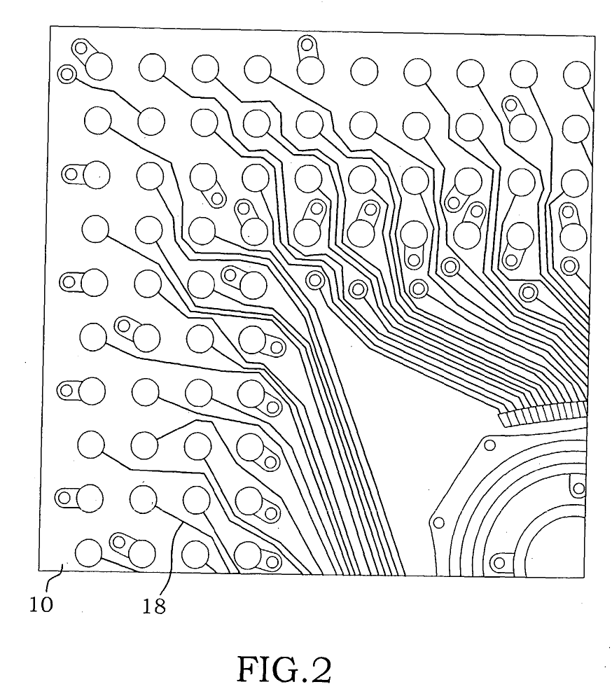

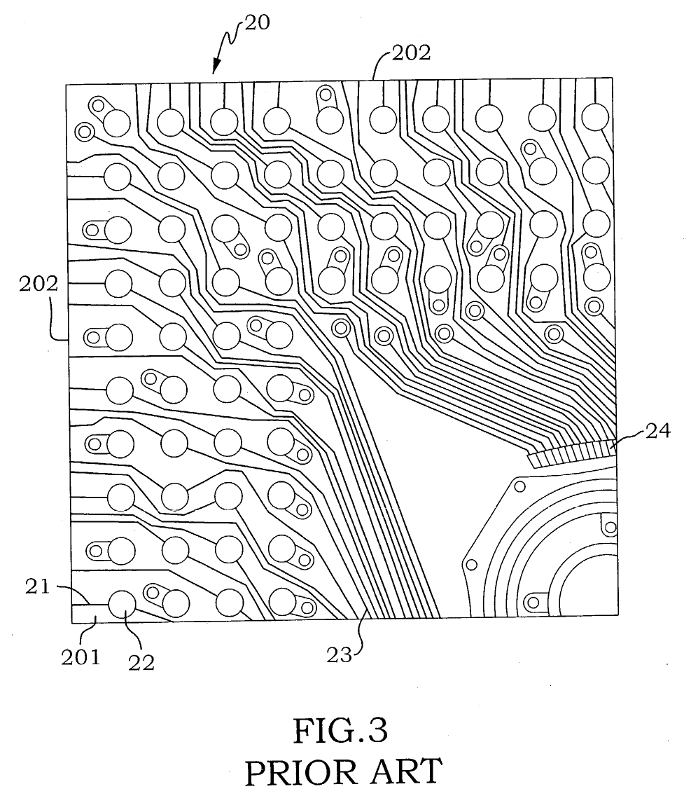

(1) High layout density. With reference to FIG. 2, a package substrate fabricated by the present invention does not have plating buses, which increases wire (18) layout area. Furthermore, electromagnetic interference associated with plating buses is completely avoided.

(2) Low cost. The Ni—Au electrolytic plating is only plated on I/O pads so the cost of the Ni—Au is lower than the FBG process and the solder resist can be directly and securely covered on the copper wires.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A stacking photoresist image transferring method for fabricating a packaging substrate comprising:
(a) preparing a substrate having two opposite faces;
(b) forming two thin base copper coatings respectively on the two faces, wherein each copper coating has a thickness;
(c) defining a first pattern of copper plating areas on each thin base copper coatings by a first photoresist using a photoresist image transferring process;
(d) plating a copper layer in the copper plating areas as copper wires and I/O pads;
(e) defining a second pattern of Ni—Au electrolytic plating areas on the I/O pads with a second photoresist using a photoresist image transferring process;
(f) plating Ni—Au in the Ni—Au electrolytic plating areas on the I/O pads;
(g) removing the first and second photoresist, wherein portions of each thin base copper layer covered by the first photoresist is exposed;
(h) flash etching the exposed thin base copper coatings; and
(i) printing a solder resist pattern on the copper wires.

2. The method as claimed in claim 1, wherein the step of forming two thin base copper coatings further comprises a reducing the thickness of each copper coating step.

3. The method as claimed in claim 2, wherein the thickness of the copper coating is about 1 to 5 um.

4. The method as claimed in claim 3, wherein the reducing thickness step is a chemical mechanical polishing (CMP) technique.

5. The method as claimed in claim 3, wherein the reducing thickness step is an etching technique.

6. The method as claimed in claim 1, wherein the first and second photoresist is a dry film.

7. The method as claimed in claim 1, wherein the first and second photoresist is a liquid film.

8. The method as claimed in claim 1, wherein the first and second photoresist is a solder mask.

9. The method as claimed in claim 1, wherein the first and second photoresist is a removable UV curing resin.

10. The method as claimed in claim 1, wherein in the removing the first and second photoresist step, the first and second photoresit is removed by one stripping technique.
